(19) United States
(12) Patent Application Publication
(10) Pub. No.: US 2013/0003300 A1
(43) Pub. Date: Jan. 3, 2013

(54) ELECTRONIC DEVICE WITH CASE FOR ELECTRO MAGNETIC COMPATIBILITY

(75) Inventors: SHUANG FU, Shenzhen City (CN); YANG LI, Shenzhen City (CN)

(73) Assignees: HON HAI PRECISION INDUSTRY CO., LTD., Tu-Cheng (TW); HON FU JIN PRECISION INDUSTRY (ShenZhen) CO., LTD., Shenzhen City (CN)

(21) Appl. No.: 13/447,265

(22) Filed: Apr. 15, 2012

(30) Foreign Application Priority Data
Jun. 30, 2011 (CN) 201110181595.1

(51) Int. Cl. H05K 7/20

(52) U.S. Cl. 361/697

(57) ABSTRACT

An electronic device includes a display module, a motherboard, a heat dissipating device, a case, and a cover. The motherboard is secured on the display module. A first heat generating member is secured to the motherboard. The heat dissipating device is secured to the motherboard. The heat dissipating device includes a heat sink and a heat pipe secured to the heat sink. The heat pipe capable of transferring heat generated from the first heat generating member to the heat sink. The case is secured to the display module and covers the motherboard. A fan module is secured to the case above the first heat generating member and capable of directing air out of the case. The cover is secured to the display module and covers the heat dissipating device and the case. The heat sink is located in the case and out of the cover.

### BACKGROUND

1. Technical Field

The present disclosure relates to electronic devices, and particularly to an electronic device with a case for increasing electro magnetic compatibility.

2. Description of Related Art

Many all-in-one computers, include a metal case to cover a motherboard for increasing electro magnetic compatibility (EMC). At this time, the metal case is limited and because of the limits a heat sink cannot be directly secured on a central process unit (CPU) of the motherboard to quickly dissipate heat generated from the CPU. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is similar to FIG. 1, but viewed in a different aspect.

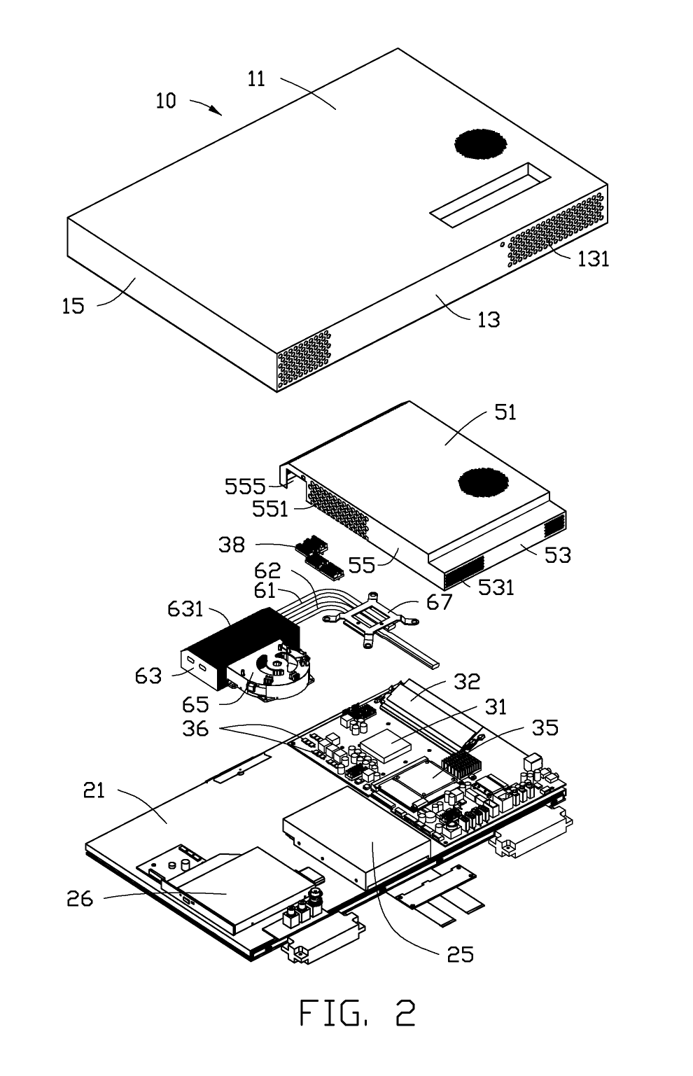

FIG. 3 is an isometric view of a case of FIG. 1.

FIG. 4 is similar to FIG. 1, but showing a heat dissipating device secured to a motherboard of the electronic device of FIG. 1.

FIG. 5 is an isometric view of an assembly of the electronic device of FIG. 1, and the cover is not shown.

FIG. 6 is similar to FIG. 5, but the cover is shown.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

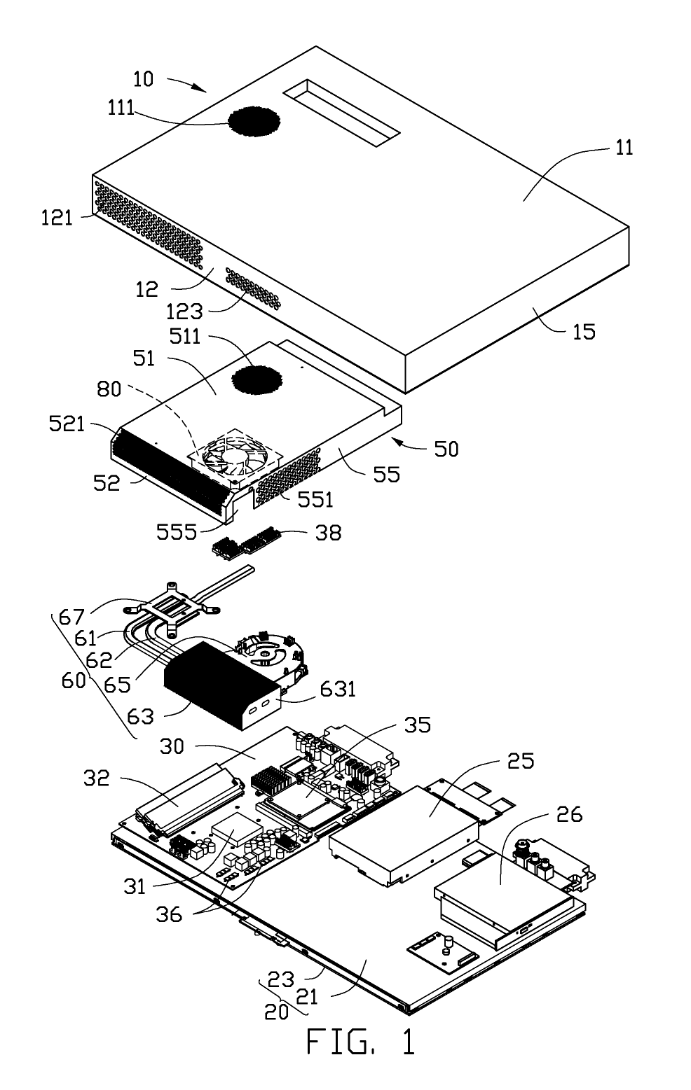

Referring to FIG. 1, an electronic device in accordance with an embodiment includes a display module 20, a heat dissipating device 60, a case 50, and a cover 10.

The display module 20 includes a display panel 23 and a back plane 21. The back plane 21 is secured on a rear side of the display panel 23. In an embodiment, the display panel 23 includes a screen, and the back plane 21 is a liquid crystal display (LCD) or Light Emitting Diode (LED) back plane. A motherboard 30, a first disk drive 25, and a second disk drive 26 are secured to the back plane 21 on a rear side. For example, the first disk drive 25 may be a hard disk drive, and the second disk drive 26 may be a compact disc read-only memory drive. The first disk drive 25 is located between the motherboard 30 and the second disk drive 26. A first heat generating member 31, a plurality of memory cards 32, a second heat generating member 35, and a plurality of third heat generating members 36 is located on the motherboard 30. The first heat generating member 31 is located between the memory cards 32 and the third heat generating members 36, and the second heat generating member 35 is located on a side of the first heat generating member 31 and the third heat generating members 36. The second heat generating member 35 and the third heat generating members 36 are adjacent the first disk drive 25, and the memory cards 32 are away from the first disk drive 25. A heat dissipating member 38 can be secured to the motherboard 30 for dissipating heat generated from the third generating members 36. In an embodiment, the first heat generating member 31 is a central process unit (CPU), the second heat generating member 35 is a chip of a color graphics adapter, and the third heat generating members 36 are metal-oxide-semiconductor field-effect transistors.

The heat dissipating device 60 is attachable to the motherboard 30. The heat dissipating device 60 includes a heat sink 63, a first heat pipe 61, a second heat pipe 62, a seat 67 and a first fan module 65. The heat sink 63 includes a plurality of fins 631, and the fins 631 are substantially parallel to each other. The first heat pipe 61 and the second heat pipe 62 are secured to the heat sink 63 and extend through the fins 631. The seat 67 is secured to the first heat pipe 61 and the second heat pipe 62. The first fan module 65 is secured to the heat sink 63.

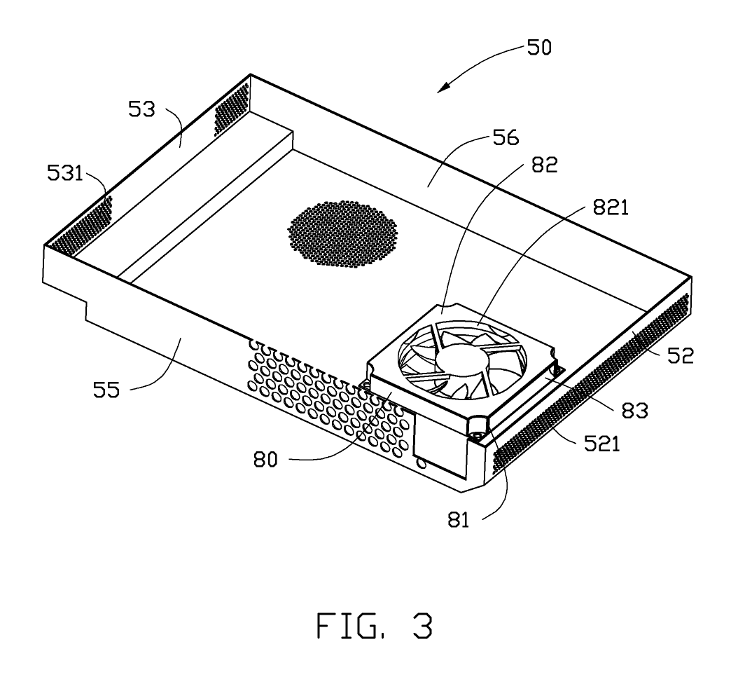

Referring to FIGS. 1 and 3, the case 50 is capable of increasing electro magnetic compatibility and includes a top wall 51, a front wall 53, a rear wall 52, a first sidewall 55, and a second sidewall 56 (shown in FIG. 3). The front wall 53, the rear wall 52, the first sidewall 55, and the second sidewall 56 extend down from four edges from the top wall 51. In an embodiment, the first sidewall 55 and the second sidewall 56 are substantially parallel to each other and perpendicular to the top wall 51, the front wall 53 and the rear wall 52. The front wall 53 defines a plurality of front wall holes 531. The top wall 51 defines a plurality of top wall holes 511. The rear wall 52 defines a plurality of rear wall holes 521. The first sidewall 55 defines a plurality of sidewall holes 551 and a cutout 555. A second fan module 80 is installed in the case 50 on an inner surface of the top wall 51 in a corner between the first sidewall 55 and the rear wall 52. The second fan module 80 includes a top board 82 and a side board 81. In an embodiment, the top board 82 is substantially perpendicular to the side board 81. The top board 82 defines a top board opening 821 for air flowing in the second fan module 80, and the side board 81 defines a side board opening 83 for air flowing out of the second fan module 80. The top board 82 is substantially parallel to the top wall 51 and perpendicular to the rear wall 52. The side board opening 83 faces the rear wall holes 521. In an embodiment, the case 50 is made of a metal piece.

Referring also to FIGS. 1 and 3, the cover 10 includes a top plate 11, a front plate 13, a rear plate 12 and two side plates 15. The front plate 13, the rear plate 12, and the side plates 15 extend down from the top plate 11. In an embodiment, the top plate 11 is substantially perpendicular to the front plate 13, the rear plate and the side plates 15; and the front plate 13 is substantially parallel to the rear plate 12 and perpendicular to the side plates 15. The top plate 11 defines a plurality of top plate holes 111. The front plate 13 defines a plurality of front plate holes 131 at two opposite end portions. The rear plate 12 defines a plurality of first rear plate holes 121 and a plurality of second rear plate holes 123.

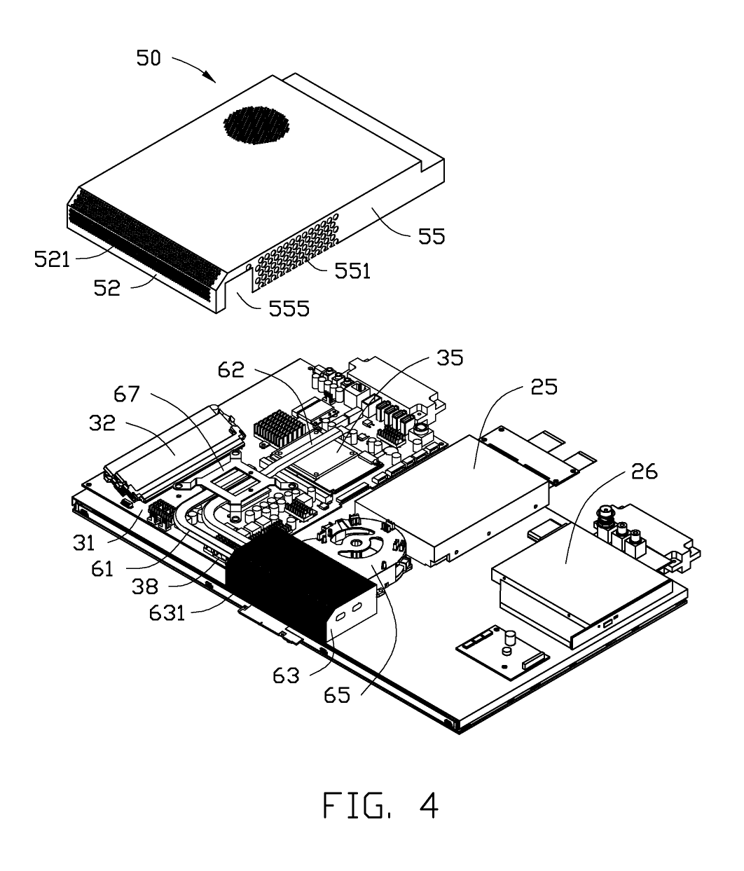

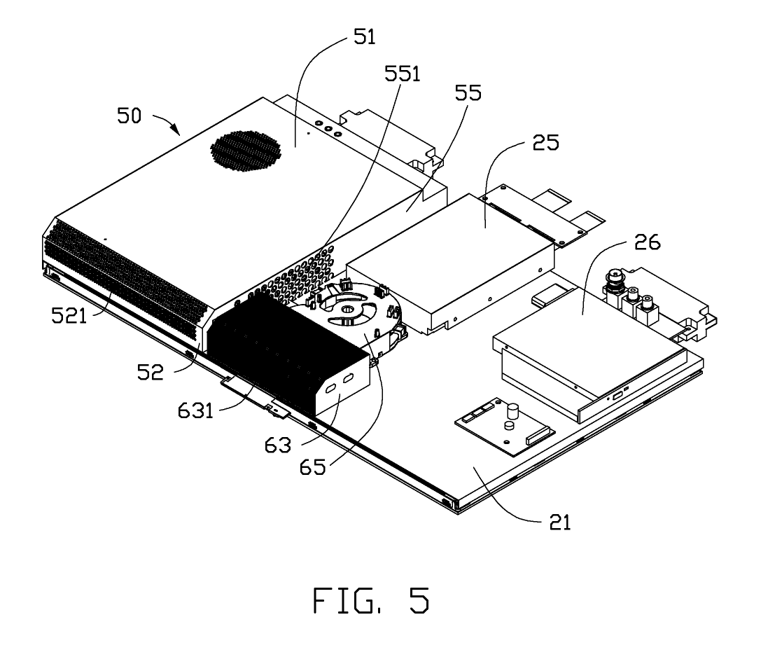

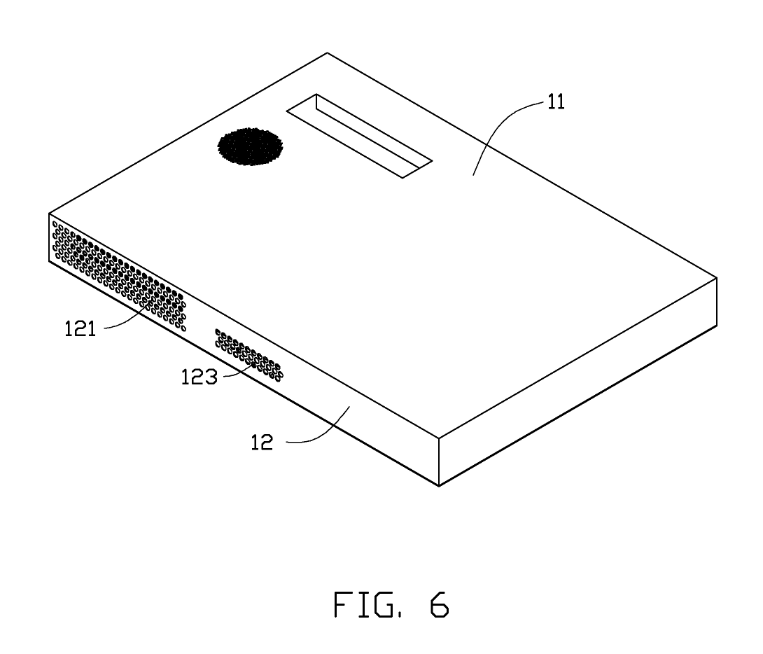

Referring to FIGS. 4-6, in assembly, the heat sink 63 is located in a corner between the motherboard 30 and the first disk drive 25. The first fan module 65 is located between the heat sink 63 and the first disk drive 25. The first heat pipe 61 and the second heat pipe 62 pass across the heat dissipating member 38 and abut the first heat generating member 31. The second heat pipe 62 also abuts the second heat generating member 35. The seat 67 is located above the first heat generating member 31 and secured to the motherboard 30 by fasteners (not shown), such as screws, to secure the first heat pipe 61 and the second heat pipe 62 to the motherboard 30. The case 50 is placed on the back plane 21 to cover the motherboard 30. The cutout 555 of the first sidewall 55 receives the first heat pipe 61 and the second heat pipe 62. The first sidewall 55 is located between the motherboard 30 and the first disk drive 25, and the fins 631 are substantially perpendicular to the first sidewall 55 and the top wall 51. The rear wall 52 is located adjacent the memory cards 32 and the third heat generating members 36. The first fan module 65 is adjacent the sidewall holes 551. The cover 10 is secured to the display module 20 to cover the back plane 21, the first disk drive 25, the second disk drive 26, the heat dissipating device 60 and the case 50. The rear wall 52 is located between the rear plate 12 and the motherboard 30. The side plates 15 are substantially parallel to the first sidewall 55 and the second sidewall 56, and the first sidewall 55 and the second sidewall 56 are substantially perpendicular to the rear plate 12.

In use, air flows in the cover 10 via the top plate holes 111, the front plate holes 131 and the sidewall holes 551. The air in the cover 10 flows in the case 50 via the top wall holes 511 and the front plate holes 131, directed by the second fan module 80 to flow out of the case 50 via the rear wall holes 521, and then flows out of the cover 10 via the first rear plate holes 121. The air in the cover 10 also flows across the first disk drive 25, the second disk drive 26, and is directed by the first fan module 65 through the heat sink 63 to flow out of the cover 10 via the second rear plate holes 123. Therefore, heat, generated from the first heat generating member 31, the second heat generating member 35, the third heat generating members 36, the memory cards 32, can be dissipated out of the cover 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a display module;
a motherboard secured on a rear side of the display module, a first heat generating member secured to the motherboard;
a heat dissipating device secured to the motherboard, the heat dissipating device comprising a heat sink and a heat pipe secured to the heat sink, the heat pipe capable of transferring heat generated from the first heat generating member to the heat sink;
a case, secured to the display module, that covers the motherboard, a fan module secured to an inner surface of the case above the first heat generating member, the fan module capable of directing air out of the case; and
a cover, secured to the display module on the rear side, that covers the heat dissipating device and the case;
wherein the heat sink is located in the case and out of the cover.

2. The electronic device of claim 1, wherein a second heat generating member is secured to the motherboard, and the heat pipe abuts the first heat generating member and the second heat generating member.

3. The electronic device of claim 2, wherein the first heat generating member is a central processing unit, and the second heat generating member is a chip of a color graphics adapter.

4. The electronic device of claim 1, wherein the case comprises a top wall, a front wall, a rear wall, a first sidewall, and a second sidewall; the front wall, the rear wall, the first sidewall and the second sidewall extends from four edges of the top wall; the first sidewall and the second sidewall are connected to the front wall and the rear wall; the front wall defines a plurality of front wall holes, the rear wall defines a plurality of rear wall holes, and the first sidewall defines a plurality of sidewall holes; the fan module is located adjacent the first sidewall and the rear wall; air is capable of flowing in the case via the plurality of front wall holes and the plurality of sidewall holes and flowing out the case via the plurality of rear wall holes when directed by the fan module.

5. The electronic device of claim 4, wherein the top wall defines a plurality of top wall holes for the air flowing into the case.

6. The electronic device of claim 4, wherein the first sidewall and the second sidewall are substantially perpendicular to the front wall and the rear wall.

7. The electronic device of claim 4, wherein the first sidewall is located between the fan module and the heat sink, and the first sidewall defines a cutout, and the heat pipe is located in the cutout.

8. The electronic device of claim 1, wherein the cover comprises a top plate, a front plate, a rear plate and two side plates; the front plate, the rear plate and the two side plates extends from four edges of the top plate; the two side plates are connected to the front plate and the rear plate; the front plate defines a plurality of front plate holes, for air flowing in the cover; and the rear plate defines a plurality of first rear plate holes and a plurality of second rear plate holes, for flowing air out of the cover.

9. The electronic device of claim 8, wherein the two side plates are substantially parallel to each other and perpendicular to the front plate and the rear plate.

10. The electronic device of claim 1, wherein the display module comprises a display panel and a back plane secured to the display panel, and the motherboard is secured to the back plane.

11. An electronic device comprising:
a display module;
a motherboard secured on a rear side of the display module, a first heat generating member secured to the motherboard;
a heat dissipating device secured to the motherboard, the heat dissipating device comprising a heat sink and a heat pipe secured to the heat sink, the heat pipe is capable of transferring heat generated from the first heat generating member to the heat sink; and
a case, secured to the display module, that covers the motherboard; the case comprising a top wall, a front wall, a rear wall, a first sidewall, and a second sidewall; the front wall, the rear wall, the first sidewall and the second sidewall extending from the top wall; the first sidewall and the second sidewall connected to the front wall and the rear wall; the motherboard located between the front wall and the rear wall and between the first sidewall and the second sidewall; a fan module secured to an inner surface of the top wall above the first heat generating member; the fan module capable of directing air out of the case; the first sidewall located between the motherboard and the heat sink.

12. The electronic device of claim 11, wherein a second heat generating member is secured to the motherboard, and the heat pipe abuts the first heat generating member and the second heat generating member.

13. The electronic device of claim 12, wherein the first heat generating member is a central processing unit, and the second heat generating member is a chip of a color graphics adapter.

14. The electronic device of claim 11, wherein the front wall defines a plurality of front wall holes, the rear wall defines a plurality of rear wall holes, and the first sidewall defines a plurality of sidewall holes; the fan module is located adjacent the first sidewall and the rear wall; and air is capable of flowing in the case via the plurality of front wall holes and the plurality of sidewall holes and flowing out the case via the plurality of rear wall holes when directed by the fan module.

15. The electronic device of claim 14, wherein the top wall defines a plurality of top wall holes for the air flowing into the case.

16. The electronic device of claim 14, wherein the first sidewall and the second sidewall are substantially perpendicular to the front wall and the rear wall.

17. The electronic device of claim 11, further comprising a cover secured to the rear side of the display module, wherein the cover comprises a top plate, a front plate, a rear plate and two side plates; the front plate, the rear plate and the two side plates extends from four edges of the top plate; the two side plates are connected to the front plate and the rear plate; the front plate defines a plurality of front plate holes, for air flowing in the cover; the rear plate defines a plurality of rear plate holes, for air flowing out of the cover.

18. The electronic device of claim 17, wherein the two side plates are substantially parallel to each other and perpendicular to the front plate and the rear plate.

19. The electronic device of claim 11, wherein the display module comprises a display panel and a back plane secured to the display panel, and the motherboard is secured to the back plane.

20. The electronic device of claim 11, wherein the first sidewall defines a cutout, and the heat pipe is located in the cutout.
